(19) United States
(12) Patent Application Publication
(10) Pub. No.: US 2026/0358408 A1
(43) Pub. Date: Nov. 12, 2026

(54) DIE, DEVICE AND METHOD FOR TESTING THROUGH SILICON VIA

(71) Applicants: Samsung Electronics Co., Ltd., Suwon-si (KR); Yonesi University Industry-Academic Cooperation Foundation, Seoul (KR)

(72) Inventors: Sungho KANG, Seoul (KR); Sunghoon KIM, Seoul (KR)

(73) Assignees: Samsung Electronics Co., Ltd., Suwon-si (KR); Yonsei University Industry-Academic Cooperation Foundation, Seoul (KR)

(21) Appl. No.: 19/535,396

(22) Filed: Feb. 10, 2026

(30) Foreign Application Priority Data
May 9, 2025 (KR) 10-2025-0060717

(51) Int. Cl. G01R 31/28; H10W 90/20; H10W 90/26

(52) U.S. Cl. CPC G01R 31/2884; H10W 90/26; H10W 90/297

(57) ABSTRACT

Provided is a die including: a scan bus configured to propagate a test signal and a response signal; a plurality of cores; a plurality of through silicon vias (TSVs); a plurality of core scanners configured to be connected to the scan bus, to provide a first test signal to the plurality of cores, and to receive a first response signal from the plurality of cores; and a first TSV scanner configured to be connected to the scan bus and to provide a second test signal to a first TSV set including at least one first TSV of the plurality of TSVs.

### CROSS-REFERENCE TO RELATED APPLICATION

This application claims the benefit of Korean Patent Application No. 10-2025-0060717, filed on May 9, 2025, in the Korean Intellectual Property Office, the disclosure of which is incorporated herein by reference in its entirety.

### BACKGROUND

### Field

The present disclosure relates to a die included in an integrated semiconductor device, and more specifically, to a die for testing a through silicon via (TSV), and a device and a method therefor.

### Description of Related Art

As there has been a demand for greater integration and performance, a three-dimensional integrated semiconductor structure, in which a plurality of dies are integrated, is introduced to overcome an area limitation of a single die (or chip). Accordingly, a design for test (DFT) for the entire integrated semiconductor device including a connection between dies, not only for an individual die internal circuit, has been required. In particular, since a test of the integrated semiconductor device presumes a die that has passed a test, greater emphasis is placed on a test of connections for communication between dies, for example, a TSV test. A structure and a method for effectively performing such a TSV test are required.

### SUMMARY

Provided is a die capable of effectively performing a TSV test, and a device and a method thereof.

According to an aspect of the disclosure, a die includes: a scan bus configured to propagate a test signal and a response signal; a plurality of cores; a plurality of through silicon vias (TSVs); a plurality of core scanners configured to be connected to the scan bus, to provide a first test signal to the plurality of cores, and to receive a first response signal from the plurality of cores; and a first TSV scanner configured to be connected to the scan bus and to provide a second test signal to a first TSV set including at least one first TSV of the plurality of TSVs.

According to an aspect of the disclosure, a device includes: a first die including a first scan bus; a second die including a second scan bus; and a plurality of first through silicon vias (TSVs) connecting the first die and the second die, wherein the first die includes a first TSV scanner configured to receive a first test signal through the first scan bus and to provide the first test signal to a first TSV set including at least one of the plurality of first TSVs, and wherein the second die includes a second TSV scanner configured to receive a first response signal from the first TSV set and to transmit the first response signal through the second scan bus.

According to an aspect of the disclosure, a method of testing a device including a first die and a second die includes: acquiring, in the first die, a first test signal from a first scan bus; providing, in the first die, the first test signal to a first through silicon via (TSV) set including at least one of a plurality of first TSVs; acquiring, in the second die, a first response signal from the first TSV set; and transmitting, in the second die, the first response signal through a second scan bus.

According to one or more embodiments of the present disclosure, a die, a device and a method may enable efficient provision of a test signal, thereby reducing a test time of an integrated semiconductor device and lowering overall test costs.

According to one or more embodiments of the present disclosure, the die, the device and the method may enable accurate identification of a location and a type of a TSV defect, thereby enhancing the reliability of the integrated semiconductor device that has passed a test.

According to one or more embodiments of the present disclosure, the die, the device and the method may enable a structure of testing cores included in a die to be used for a TSV test, thereby increasing the efficiency of the TSV test of the integrated semiconductor device and minimizing hardware overhead for the test.

The effects obtainable from example embodiments of the present disclosure are not limited to those mentioned above, and other effects not explicitly described may be clearly derived and understood by those skilled in the art from the following description. That is, even unintended effects resulting from the implementation of example embodiments of the present disclosure may also be derived by those skilled in the art from example embodiments of the present disclosure.

### BRIEF DESCRIPTION OF DRAWINGS

These and/or other aspects and features of the present disclosure will become more readily apparent from the following description taken in conjunction with the accompanying drawings, in which:

FIG. 1 is a block diagram showing an integrated semiconductor device according to one or more embodiments of the present disclosure;

FIG. 2 is a block diagram showing a structure for a test of an integrated semiconductor device according to one or more embodiments of the present disclosure;

FIG. 3 is a diagram showing a die according to one or more embodiments of the present disclosure;

FIG. 4 illustrates examples of a TSV set according to one or more embodiments of the present disclosure;

FIG. 5 is a block diagram showing a die according to one or more embodiments of the present disclosure;

FIGS. 6A and 6B are block diagrams showing a TSV test structure in an integrated semiconductor device according to one or more embodiments of the present disclosure;

FIG. 7 is a block diagram showing a test structure of an integrated semiconductor device according to one or more embodiments of the present disclosure;

FIG. 8 is a flowchart showing a device test method according to one or more embodiments of the present disclosure;

FIG. 9 is a flowchart showing a device test method according to one or more embodiments of the present disclosure;

FIG. 10 is a flowchart showing a method of providing a test signal according to one or more embodiments of the present disclosure;

FIG. 11 is a flowchart showing a method of transmitting a control signal to another die according to one or more embodiments of the present disclosure; and

FIG. 12 is a flowchart showing a method of receiving a test signal in a die according to one or more embodiments of the present disclosure.

### DETAILED DESCRIPTION

In the following description, like reference numerals refer to like elements throughout the specification. Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection may include “connection via a wireless communication network”.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure is not be limited by these terms, and these terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

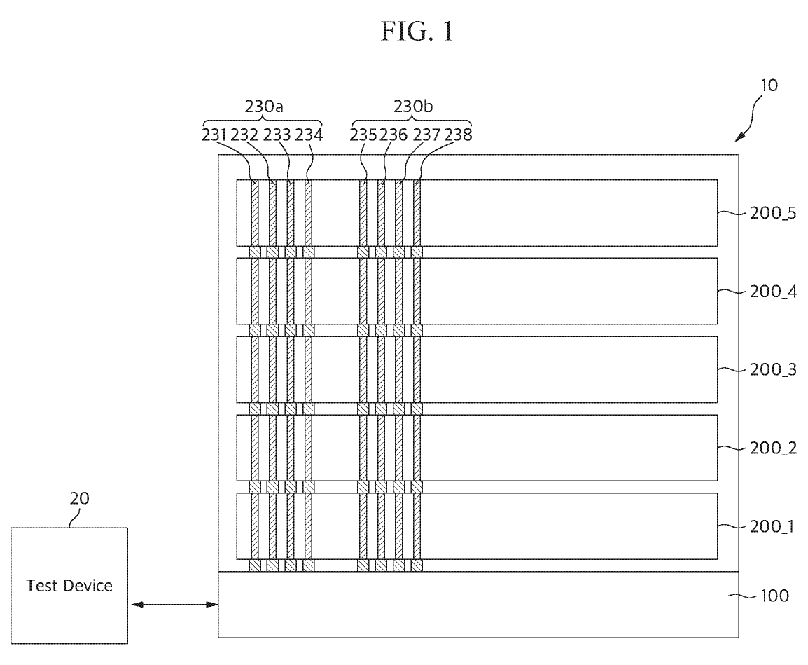

FIG. 1 is a block diagram showing an integrated semiconductor device 10 according to one or more embodiments of the present disclosure. As illustrated in FIG. 1, the integrated semiconductor device 10 may include a first die 200_1 to a fifth die 200_5 integrated on a substrate 100. The number of dies integrated in the integrated semiconductor device 10 is not limited to that illustrated in FIG. 1.

Each of the plurality of dies 200_1 to 200_5 included in the integrated semiconductor device 10 may be a die that has passed a test. The first die 200_1 to the fifth die 200_5 may be integrated on the substrate 100 and included in a package of the integrated semiconductor device 10, and may communicate through silicon vias (TSVs), for example, a first TSV 231 to an eighth TSV 238. That is, the first die 200_1 to the fifth die 200_5 may transmit and receive data to and from one another through the first TSV 231 to the eighth TSV 238, and may transmit and receive test data and response data corresponding to the test data according to one or more embodiments of the present disclosure. Tests of the integrated semiconductor device 10 may include a test of a connection between dies through the first TSV 231 to the eighth TSV 238. As will be described below with reference to the drawings, the integrated semiconductor device 10 may provide a structure for efficiently testing the connection between the dies.

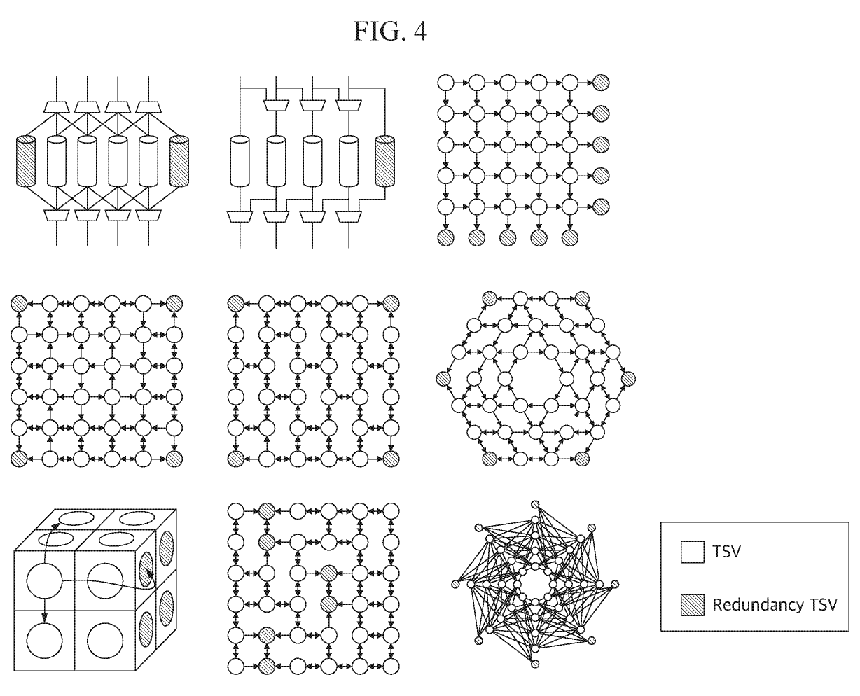

The first TSV 231 to the eighth TSV 238 may be grouped into a first TSV set 230a and a second TSV set 230b. For example, as illustrated in FIG. 1, the first TSV 231 to a fourth TSV 234 may be grouped into the first TSV set 230a, and a fifth TSV 235 to the eighth TSV 238 may be grouped into the second TSV set 230b. The first TSV 231 to the eighth TSV 238 may be grouped into a TSV set based on various types and patterns, and the TSV set may include at least one redundancy TSV. Accordingly, when a specific defective TSV included in the TSV set is detected during a test process of the integrated semiconductor device 10, a connection of the TSV set may be repaired by replacing the defective TSV with a corresponding redundancy TSV in the TSV set. That is, when a defective TSV is detected in the first die 200_1 to the fifth die 200_5, for repairing the defective TSV, the first TSV 231 to the eighth TSV 238 may be grouped into the first TSV set 230a and the second TSV set 230b. To this end, the TSV set may be configured in a manner in which a TSV corresponds to at least one redundancy TSV. Various example embodiments related thereto will be described with reference to FIG. 4. The number of TSVs and the number of TSV sets included in the integrated semiconductor device 10 are not limited to that illustrated in FIG. 1.

The integrated semiconductor device 10 may communicate with an external test device 20 for detecting whether there is a defect. The integrated semiconductor device 10 may include a structure for a test of the first die 200_1 to the fifth die 200_5 based on test data and control signals received from the test device 20. For example, each of the first die 200_1 to the fifth die 200_5 may include a test access port (TAP) and include a path for the test data and the response data, and a circuit for controlling the path. The test device may provide the integrated semiconductor device 10 with a test signal for testing whether the integrated semiconductor device 10 is defective and/or whether the integrated semiconductor device 10 operates in accordance with a pre-design, and receive the response data corresponding to the test signal from the integrated semiconductor device 10. For example, the test device 20 may be referred to as automatic test equipment (ATE) for automatically testing the integrated semiconductor device 10.

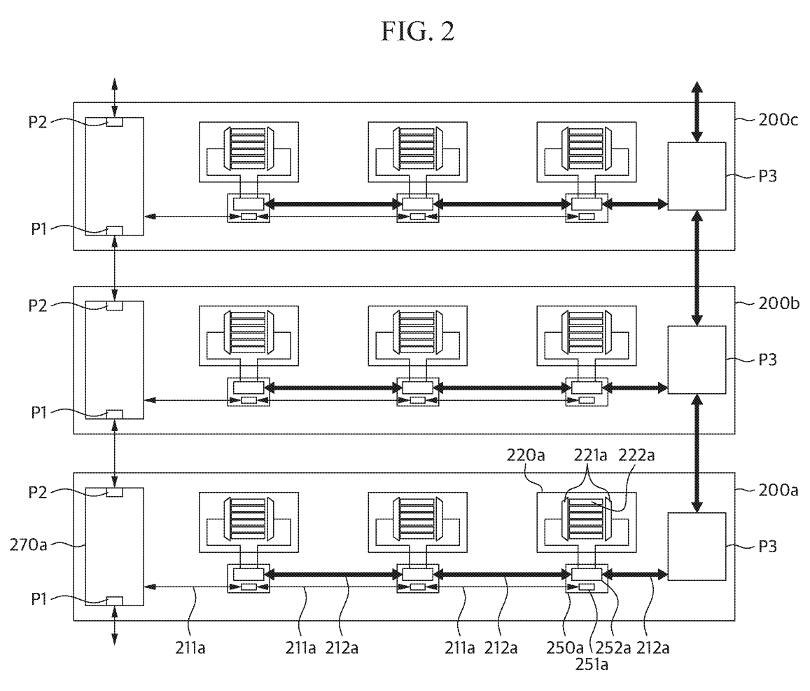

FIG. 2 is a block diagram showing a structure for a test of an integrated semiconductor device 10 according to one or more embodiments of the present disclosure. For example, FIG. 2 illustrates a data path for propagating a test signal and a response signal, and a path of a control signal that controls a test circuit included in a die inside the integrated semiconductor device 10. As described above with reference to FIG. 1, a first die 200a to a third die 200c may be integrated sequentially in the integrated semiconductor device 10.

In one or more embodiments, the integrated semiconductor device 10 may provide a streaming scan network (SSN). For example, as illustrated in FIG. 2, the first die 200a may include a first test controller 270a, a first control signal line 211a, a first scan bus 212a, a first core 220a, and a first core scanner 250a. A second die 200b and the third die 200c may each have structures identical to the first die 200a. The first die 200a will be mainly described below as a representative example.

A core, as an entity that performs an independent function in the first die 200a to the third die 200c, may be a test unit and include a structure for a test. For example, as illustrated in FIG. 2, a first core 220a may include a first compression logic 221a and a first scan chain 222a. The first compression logic 221a may compress or decompress test data and/or response data. The first scan chain 222a may propagate the decompressed data.

Based on a control signal received through the first control signal line 211a, the first core scanner 250a may identify test data checked in the first scan bus 212a, transmit the test data to the first core 220a, and receive response data from the first core 220a. The first core scanner 250a may include a first signal register 251a and a first bus register 252a. The first signal register 251a may latch the control signal received from the first test controller 270a. The first bus register 252a may latch data received through the first scan bus 212a. In the first die 200a, the first core scanner 250a may be connected to the first scan bus 212a and function as a node of the SSN by identifying the test data corresponding to the first core 220a.

The first test controller 270a may receive the control signal related to the test of the integrated semiconductor device 10 and control the first core scanner 250a through the first control signal line 211a based on the control signal. As illustrated in FIG. 2, the first test controller 270a may include a first port P1 and a second port P2. In one or more embodiments, the first test controller 270a may receive a first control signal through the first port P1, generate a second control signal based on the first control signal, and output the second control signal through the second port P2. The first control signal line 211a is a signal line for the first test controller 270a to control the first core scanner 250a and, in one or more embodiments, may have a smaller bandwidth than that of the first scan bus 212a.

The first scan bus 212a may be connected to core scanners included in the first die 200a. A packet of the test data may be transmitted through the first scan bus 212a. The first scan bus 212a may be connected through a third port P3 to a scan bus included in another die. The third port P3 may have a greater bandwidth than the first port P1 and/or the second port P2. The third port P3 may be referred to as a flexible parallel port (FPP). Accordingly, scan buses included in each of the first die 200a to the third die 200c may be connected and communicate with core scanners included in the integrated semiconductor device 10. Accordingly, the SSN may be implemented in the integrated semiconductor device 10.

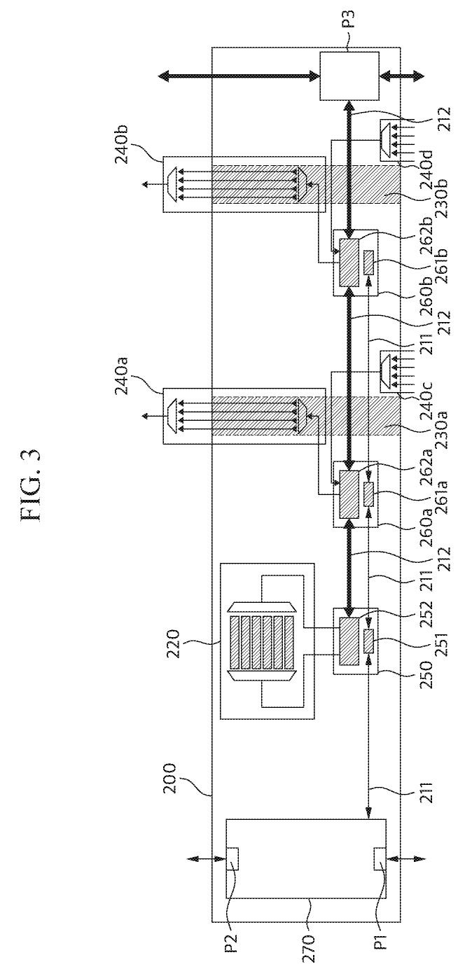

FIG. 3 is a diagram showing a die 200 according to one or more embodiments of the present disclosure. For example, the die 200 illustrated in FIG. 3 may correspond to one of the first die 200_1 to the fifth die 200_5 illustrated in FIG. 1.

Referring to FIG. 3, the die 200 may include a control signal line 211, a scan bus 212, a core 220, a core scanner 250, a first TSV set 230a and a second TSV set 230b, and a first TSV scanner 260a and a second TSV scanner 260b. As described above with reference to FIG. 1, each of the first TSV set 230a and the second TSV set 230b may include a plurality of TSVs that include at least one redundancy TSV.

The core scanner 250 may be connected to the scan bus 212, provide test data to the core 220, and receive response data from the core 220. The first TSV scanner 260a may be connected to the scan bus 212 and provide a test signal to the first TSV set 230a. The second TSV scanner 260b may be connected to the scan bus 212 and provide the test signal to the second TSV set 230b. For convenience, FIG. 3 illustrates only one core 220, however, as described above with reference to FIG. 2, the die 200 may include a plurality of cores.

The TSV is for a connection between dies in an integrated semiconductor structure. The test signal for testing the connection between dies may be input into a target TSV to be tested in a specific die, and a response signal may be received in another die connected through the target TSV to be tested. Accordingly, a transmission end for providing the test signal to the first TSV set 230a and the second TSV set 230b may be included in the die 200. However, a reception end for receiving the response signal to the test signal from the first TSV set 230a and the second TSV set 230b may be included in another die, for example, a die disposed on the die 200. In addition, the first TSV scanner 260a and the second TSV scanner 260b may receive the response signal from TSV sets included in another die, for example, a die disposed under the die 200.

In one or more embodiments, the first TSV scanner 260a may transmit a resultant signal corresponding to a test result of a third TSV block 240c based on the test signal for TSV blocks and the response signal of the third TSV block 240c. Similarly, the second TSV scanner 260b may transmit the resultant signal corresponding to the test result of a fourth TSV block 240d through the scan bus 212 based on the test signal for TSV blocks and the response signal of the fourth TSV block 240d. The resultant signal transmitted by the first TSV scanner 260a and the second TSV scanner 260b through the scan bus 212 may be a signal related to whether a state of a connection to a TSV block is normal. The resultant signal may be generated in an output logic included in the first TSV scanner 260a and the second TSV scanner 260b, and transmitted through the scan bus 212.

FIG. 3 illustrates an example in which the first TSV scanner 260a and the second TSV scanner 260b provide the test signal to the first TSV set 230a and the second TSV set 230b included in the die 200 and receive the response signal from TSV sets included in another die. However, in one or more embodiments, a TSV scanner may receive the response signal from a TSV set included in an equal die and provide the test signal to a TSV set included in another die. In other words, a connection direction of the TSV scanner and the TSV set according to the present disclosure is not limited to that illustrated in FIG. 3. Both ends of the TSV set to which the test signal is provided, or from which the response signal is received, may include every combination included in other dies, respectively.

When the first TSV set 230a and the second TSV set 230b have one end that receives the test signal and another end connected to another die, to which the response signal to the test signal is provided, input of the test signal and output of the response signal may be performed in different dies to test the first TSV set 230a and the second TSV set 230b. Accordingly, first and second test units that include a compression logic for a TSV test signal, which are a first TSV block 240a and a second TSV block 240b, may be configured. Referring to FIG. 3, the first TSV set 230a and the second TSV set 230b included in the die 200 may be included in the first TSV block 240a and the second TSV block 240b, respectively. The first TSV scanner 260a and the second TSV scanner 260b may provide the test signal to the first TSV block 240a and the second TSV block 240b, respectively, and receive the response signal from the third TSV block 240c and the fourth TSV block 240d.

The first TSV scanner 260a and the second TSV scanner 260b are configured to be connected, similar to the core scanner 250, to a test controller 270 through the control signal line 211, to check the test signal for the first TSV block 240a and the second test block 240b in the scan bus 212 according to the control signal received through the control signal line 211 from the test controller 270, and to provide the test signal to the first TSV block 240a and the second TSV block 240b. The core scanner 250 and the first TSV scanner 260a and the second TSV scanner 260b are connected through the scan bus 212. The scan bus 212 may transmit a data packet associated with the test signal of the core 220 and the test signal of the first TSV block 240a and the second TSV block 240b. The first TSV scanner 260a may include a control signal register 261a configured to latch the control signal and a bus register 262a configured to latch data streamed in the scan bus 212. The second TSV scanner 260b may also include a control signal register 261b and a bus register 262b.

In one or more embodiments, the die 200 may further include the test controller 270 that receives the control signal through the first port P1 and controls the core scanner 250, the first TSV scanner 260a, and the second TSV scanner 260b based on the control signal received through the first port P1. The test controller 270 may be configured to generate a new control signal based on the control signal received through the first port P1 and to transmit the new generated control signal through the second port P2. In addition, the scan bus 212, which is connected to the core scanner 250, the first TSV scanner 260a, and the second TSV scanner 260b in the die 200, may be connected to a scan bus of another die through the third port P3. The scan bus 212 may be configured to receive test signals including a core test signal and the TSV test signal through the third port P3.

In one or more embodiments, the first TSV set 230a and the second TSV set 230b may correspond to an equal TSV structure. For example, each of the first TSV set 230a and the second TSV set 230b may include at least one redundancy TSV. When a specific defective TSV is checked in the response signal for the first TSV set 230a and the second TSV set 230b, the TSV sets may be repaired in a manner that replaces the connected defective TSV with the corresponding redundancy TSV. In this regard, the first TSV set 230a and the second TSV set 230b may have a predetermined repair structure related to correspondence of the TSV and the redundancy TSV. The first TSV set 230a and the second TSV set 230b may correspond to an equal repair structure.

Further, as the first TSV set 230a and the second TSV set 230b correspond to an equal structure, the first TSV block 240a and the second TSV block 240b may be considered as an equal test unit. In this case, a test of the first TSV block 240a and the second TSV block 240b may be performed based on an equal test signal. The test of the first TSV block 240a and the second TSV block 240b may be performed by an equal data packet streamed in the scan bus 212. The scan bus 212 may propagate the data packet by being connected to the first TSV scanner 260a and the second TSV scanner 260b. As the first TSV block 240a and the second TSV block 240b are considered as an equal test unit, the equal data packet may be used for the test of the first TSV block 240a and the second TSV block 240b, so that the test of the first TSV block 240a and the second TSV block 240b may be performed in parallel. Therefore, as there are more TSV blocks considered as an equal test unit in the die 200, the utilization of the data packet corresponding to the TSV test signal may proportionally increase. In other words, it may be understood that the data packet corresponding to the TSV test signal is reused in each TSV block as many times as the number of TSV blocks, thereby enabling the TSV test to be performed effectively.

FIG. 4 illustrates examples of a TSV set according to one or more embodiments of the present disclosure. The TSV set described with reference to the figures may include TSVs arranged in various forms like those illustrated in FIG. 4. The TSV set may include at least one redundancy TSV.

When a specific TSV is defective in a test process of a device, a connection may be recovered by replacing the TSV with a redundancy TSV provided in an equal TSV set. Here, the TSV set may be designed to have a redundancy TSV corresponding to each TSV, and various repair patterns may be implemented according to a correspondence relationship between the TSV and the redundancy TSV. Various arrangement examples illustrated in FIG. 4 indicate several possible repair structures.

TSV blocks may correspond to different TSV arrangements, respectively. A TSV and test data input into a TSV block may also be determined according to a TSV arrangement of the TSV block. For example, when a plurality of TSV sets have an equal TSV arrangement, a plurality of TSV blocks corresponding to the TSV sets may be considered as an equal test unit. Accordingly, a test of the TSV blocks may be performed based on an equal test signal, and a data packet for the test is streamed in parallel through scan buses and propagated to respective TSV blocks. The scan buses are connected to TSV scanners in parallel, respectively, and through this, an equal data packet may be applied to multiple TSV blocks simultaneously, thereby maximizing parallelism of the test.

Therefore, as the number of TSV blocks considered as an equal test unit increases in the die 200, the utilization of a data packet corresponding to a specific test signal proportionally increases. It may be understood that such a structure reduces time and resources required for a TSV test and enhances overall productivity and reliability.

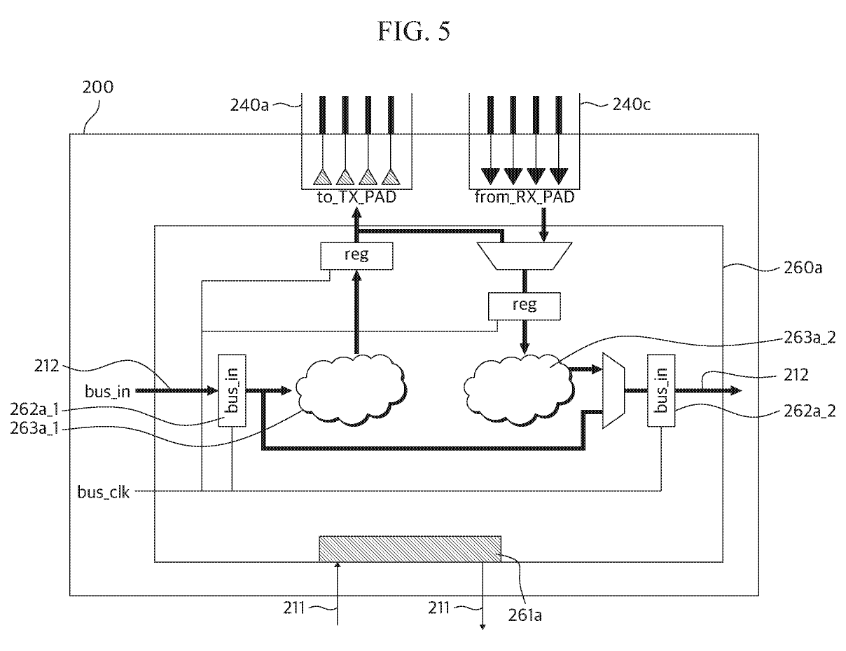

FIG. 5 is a block diagram showing a die 200 according to one or more embodiments of the present disclosure. For example, the block diagram of FIG. 5 shows a first TSV scanner 260a included in the die 200 of FIG. 3. As illustrated in FIG. 5, the first TSV scanner 260a may be connected to a first scan bus 212, provide a test signal to a first TSV block 240a, and receive a response signal from a third TSV block 240c. Hereinafter, the first TSV scanner 260a will be mainly described with reference to FIG. 5. However, a plurality of TSV scanners included in the integrated semiconductor device 10 may have an equal structure to the first TSV scanner 260a.

Referring to FIG. 5, the first TSV scanner 260a includes a first control signal register 261a that is connected to a first control signal line 211 and latches a control signal received from the test controller 270 of FIG. 3 The first control signal line 211 may provide and receive the test signal according to a test structure for components inside the die 200, and more specifically, transmit and receive signals based on a configuration and a protocol of a scan chain to and from other core scanners inside the die 200. The first TSV scanner 260a may be configured to check control setting of the first TSV scanner 260a based on the control signal checked in the first control signal register 261a.

The first TSV scanner 260a may include a first input bus register 262a_1 and a first output bus register 262a_2 that are connected to the first scan bus 212 to latch data streamed in the first scan bus 212, a first input logic 263a_1 that checks the test signal of the first TSV block 240a in the first input bus register 262a_1 and provides the test signal to the first TSV block 240a, and a first output logic 263a_2 configured to load the response signal received from a third TSV block 240c to the first output bus register 262a_2. The first output bus register 262a_2 may be configured to load streaming data transmitted from the first input bus register 262a_1 and response signal data transmitted from the first output logic 263a_2. Here, as described above, a TSV set of the first TSV block 240a to which the first input logic 263a_1 provides the test signal and a TSV set of a third TSV block 240c from which the first output logic 263a_2 receives the response signal may be composed of TSVs included in different dies.

In one or more embodiments, the first TSV scanner 260a may transmit a resultant signal corresponding to a test result of the third TSV block 240c based on the test signal for TSV blocks and the response signal of the third TSV block 240c. The first output logic 263a_2 may generate the resultant signal and transmit the resultant signal through a scan bus. The first output logic 263a_2 may be configured to check whether a connection of the third TSV block 240c is defective.

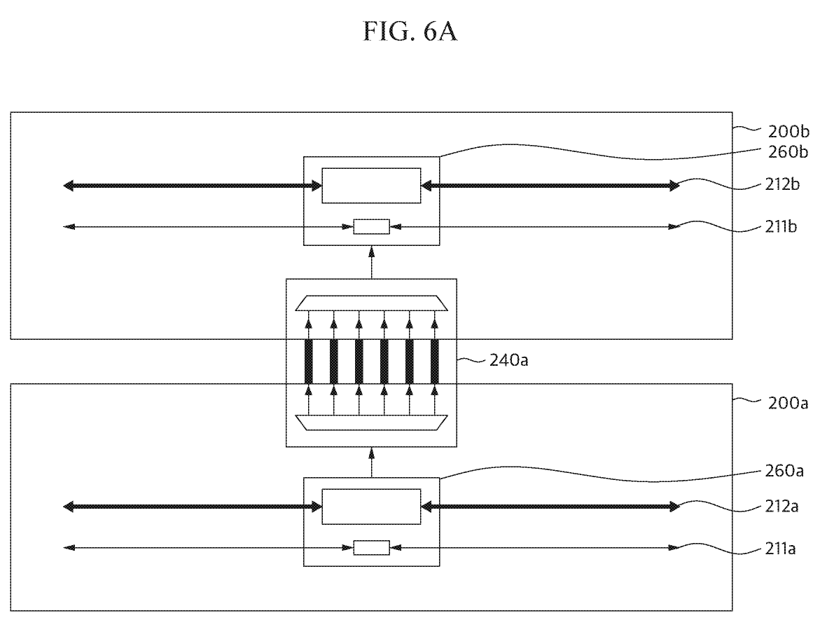

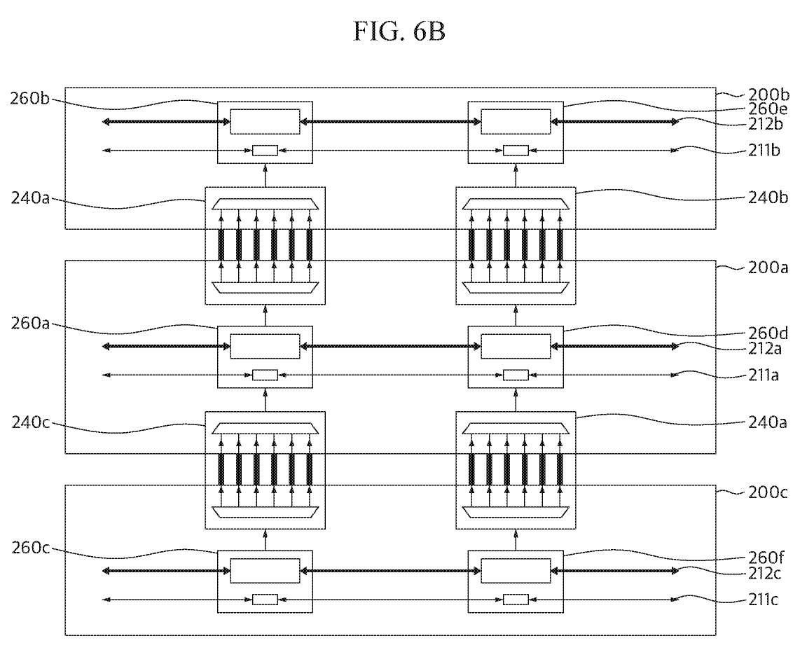

FIGS. 6A and 6B show a TSV test structure in an integrated semiconductor device 10 according to one or more embodiments of the present disclosure. FIG. 6A illustrates the TSV test structure that includes a first die 200a and a second die 200b connected corresponding to one TSV block 240a. FIG. 6B illustrates the TSV test structure in the first die 200a to a third die 200c connected corresponding to a first TSV block 240a to a fourth TSV block 240d. For convenience of description, FIGS. 6A and 6B illustrate a TSV block between dies.

Referring to FIG. 6A, the integrated semiconductor device 10 may include the first die 200a that includes a first scan bus 212a, the second die 200b that includes a second scan bus 212b, and a plurality of TSVs that connect the first die 200a and the second die 200b. The first die 200a includes a first TSV scanner 260a. The second die 200b includes a second TSV scanner 260b. The first TSV scanner may be configured to receive a test signal through the first scan bus 212a and provide the test signal to the first TSV block 240a that connects the first die 200a and the second die 200b. The second TSV scanner 260b may be configured to receive a response signal from the first TSV block 240a and transmit the response signal through the second scan bus 212b. The first TSV block 240a may include a first TSV set including at least one of the plurality of TSVs that connect the first die 200a and the second die 200b. The first TSV set may include TSVs of the first die 200a or TSVs of the second die 200b.

Referring to FIG. 6B, the integrated semiconductor device 10 may include the first die 200a that includes the first scan bus 212a, the second die 200b that includes the second scan bus 212b, the third die 200c that includes a third scan bus 212c, the plurality of TSVs that connect the first die 200a and the second die 200b, and a plurality of TSVs that connect the first die 200a and the third die 200c. The first TSV block 240a and the second TSV block 240b include the first TSV set and a second TSV set, respectively, which include at least one of the plurality of TSVs that connect the first die 200a and the second die 200b. The first TSV set and the second TSV set may include the TSVs of the first die 200a or the TSVs of the second die 200b. The third TSV block 240c and the fourth TSV block 240d include a third TSV set and a fourth TSV set, respectively, which include at least one of the plurality of TSVs that connect the first die 200a and the third die 200c. The third TSV set and the fourth TSV set may include the TSVs of the first die 200a or TSVs of the third die 200c. The first die 200a includes the first TSV scanner 260a and a fourth TSV scanner 260d. The second die 200b includes the second TSV scanner 260b and a fifth TSV scanner 260e. The third die 200c includes a third TSV scanner 260c and a sixth TSV scanner 260f. The first TSV scanner 260a to the sixth TSV scanner 260f may check the test signal through a corresponding scan bus among the first scan bus 212a to the third scan bus 212c or transmit the response signal, or provide the test signal for a corresponding TSV block among the first TSV block 240a to the fourth TSV block 240d or receive the response signal.

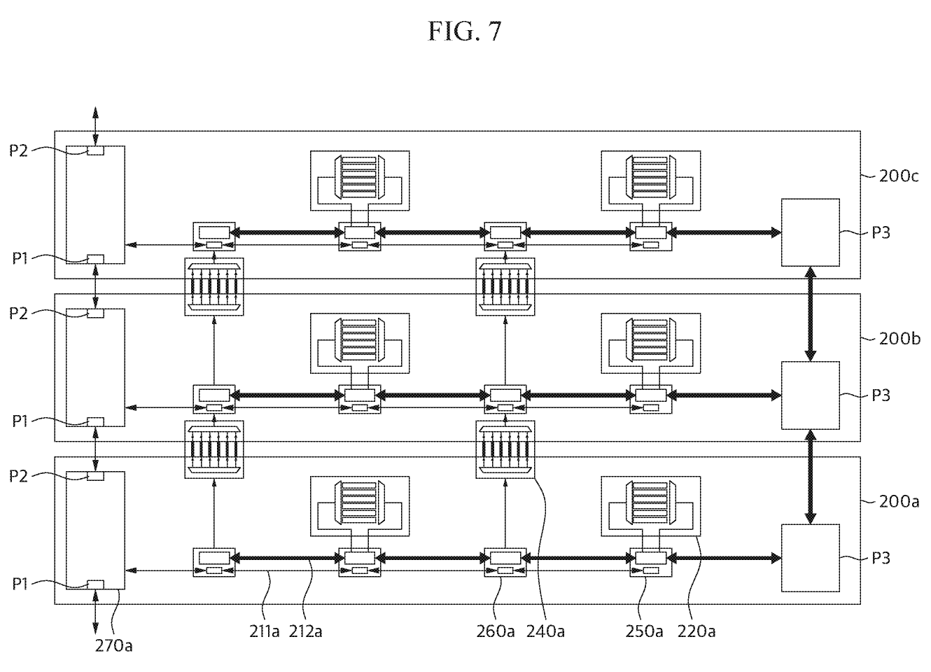

FIG. 7 is a block diagram showing a test structure of an integrated semiconductor device 10 according to one or more embodiments of the present disclosure. The integrated semiconductor device 10 of FIG. 7 illustrates an SSN structure that includes a TSV block in a test structure of the integrated semiconductor device 10 described above through FIG. 2. The test structure of the integrated semiconductor device 10 illustrated in FIG. 7, as an integrated semiconductor device 10 that includes a first die 200a to a third die 200c, may correspond to the integrated semiconductor device 10 of FIG. 2.

The test structure of the integrated semiconductor device 10 according to one or more embodiments of the present disclosure includes scan buses, cores, core scanners, and TSV scanners, which are included in each of the first die 200a to the third die 200c, and TSV blocks between the first die 200a to the third die 200c. Hereinafter, for convenience of description, the first die 200a and a first TSV block 240a will be mainly described. However, it may be understood that the descriptions related to the first die 200a and the first TSV block 240a may also be applicable to other dies and TSV blocks included in the integrated semiconductor device 10 of the present disclosure.

The first die 200a may include a first control signal line 211a, a first scan bus 212a, a first core 220a, a first core scanner 250a, a first TSV scanner 260a, a first test controller 270a, and a third port P3. The first test controller 270a may provide and receive a control signal to and from another die through a first port P1 and a second port P2. Data transmitted from the first scan bus 212a may be transmitted to a scan bus of another die through the third port P3.

The first die 200a may be connected to a second die 200b through the first TSV block 240a. The first TSV block 240a, as a test unit that includes a TSV set connecting the first die 200a and the second die 200b and a compression logic of test data, may correspond to a connection between the first die 200a and the second die 200b and be disposed between the first die 200a and the second die 200b in the block diagram of the test structure. Input of a test signal and output of a response signal of the first TSV block 240a may be performed in the first die 200a and the second die 200b, respectively, that are connected by the first TSV block 240a.

The first TSV block 240a receives the test signal for each TSV scanner that is included in each of the first die 200a and the second die 200b and provides the response signal. This contrasts with a case where the first core 220a receives the test signal from the first core scanner 250a included in the first die 200a and provides the response signal.

The second die 200b and the third die 200c may have a structure corresponding to the first die 200a. In the test structure of the integrated semiconductor device 10, the integrated semiconductor device 10 that includes the first die 200a to the third die 200c communicates the control signal, the test structure, and the response signal between the first die 200a to the third die 200c. Here, between the first die 200a to the third die 200c, the control signal may be transmitted through the first port P1 and the second port P2, and the test signal and the response signal may be transmitted through the third port P3.

In FIG. 7, each of the scan buses of the first die 200a to the third die 200c to which the test signal and the response signal are transmitted are connected through the third port P3 to form the SSN structure. In addition, a plurality of the core scanners and a plurality of the TSV scanners may function as a node of the SSN structure.

As described above with reference to the first core 220a and the first TSV block 240a, in the SSN structure of FIG. 7, there is a difference in that a core is processed by a core scanner of which a test signal and a response signal are equal while a TSV block receives the test signal for each of TSV scanners included in different dies and provides the response signal. However, although the TSV block receives the test signal for each of the TSV scanners included in different dies and provides the response signal, since the TSV blocks are connected in the SSN structure, a test for a TSV of the integrated semiconductor device 10 may be performed efficiently.

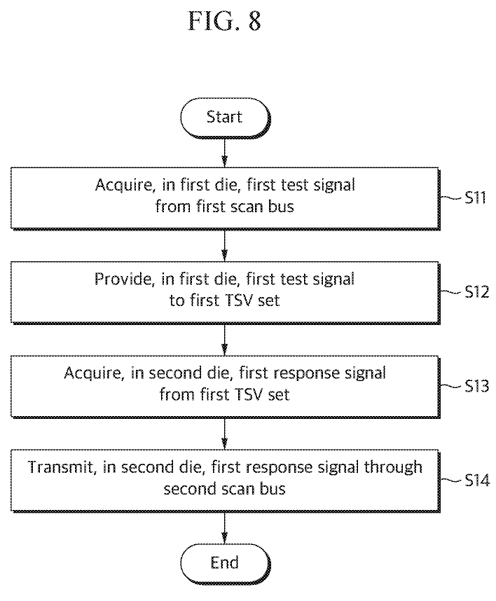

FIG. 8 is a flowchart showing a device test method according to one or more embodiments of the present disclosure. In one or more embodiments, operations of FIG. 8 may be performed in the integrated semiconductor device 10 illustrated in FIG. 6A.

The device test method according to the present disclosure may be a method of testing an integrated semiconductor device 10 that includes a first die 200a and a second die 200b. As illustrated in FIG. 8, the device test method according to one or more embodiments of the present disclosure may include a plurality of operations S11 to S14. Operation S11 and operation S12 may be performed in the first die 200a. Operation S13 and operation S14 may be performed in the second die 200b.

In operation S11, a first test signal may be acquired from a first scan bus 212a. The first test signal, as a signal for testing a TSV set, may be acquired in a form of a data packet streamed in the first scan bus 212a.

Operation S11, for example, may be performed by a first TSV scanner 260a included in the first die 200a. The first TSV scanner 260a may be configured to monitor data transmitted from the first scan bus 212a and identify a point in time at which TSV test data assigned to the first TSV scanner 260a is streamed based on a control logic set inside the first TSV scanner 260a. Test data may be transmitted consecutively through the first scan bus 212a to the first TSV scanner 260a of the first die 200a. The first TSV scanner 260a determines TSV test data to be acquired based on a specific condition set according to a control signal and acquires the TSV test data as the first test signal for testing a first TSV block 240a.

In operation S12, the first test signal may be provided to the first TSV set. Operation S12 may be performed by the first TSV scanner 260a included in the die 200a. The first TSV scanner 260a injects the first test signal acquired through the first scan bus 212a into a compression logic of a TSV block through an input control logic.

Operation S13 and operation S14 may be performed by a second TSV scanner 260b included in the second die 200b. The second TSV scanner 260b transmits a first response signal checked in the first TSV block 240a through a second scan bus 212b included in the second die 200b. According to one or more embodiments of the present disclosure, the first response signal transmitted through the second scan bus 212b may be connected to another die through a port included in the second die 200b, and the first response signal may be provided to a test device through an interface die configured to communicate with an external device.

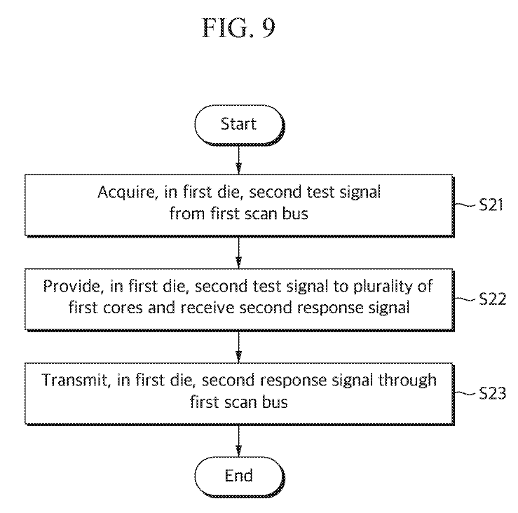

FIG. 9 is a flowchart showing a device test method according to one or more embodiments of the present disclosure. Operations of FIG. 9, for example, may be performed in each of the first die 200a to the third die 200c illustrated in FIG. 7. Hereinafter, for convenience of description, operations of FIG. 9 performed in the first die 200a of FIG. 7 will be mainly described.

Referring to FIG. 9, a device test method according to one or more embodiments of the present disclosure may include a plurality of operations S21 to S23. Operation S21 to operation S23 of FIG. 9, for example, may be performed by a core scanner 250a included in the first die 200a.

Referring to FIG. 9, a second test signal is acquired from a first scan bus 212a, and a second response signal is received from a first core 220a to be provided through the first scan bus 212a. The core scanner 250a identifies and acquires the second test signal corresponding to the first core 220a from the first scan bus 212a. The second test signal refers to a test signal for a test corresponding to the first core 220a, and the second response signal refers to a response signal of the first core 220a to the second test signal.

Unlike a TSV, a core may be processed by a core scanner of which a test signal and a response signal are equal. Accordingly, the second test signal and the second response signal for the first core 220a may be transmitted through the first scan bus 212a included in the first die 200a.

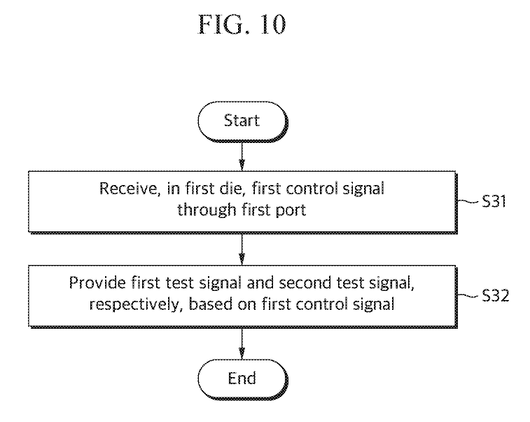

FIG. 10 is a flowchart showing a method of providing a test signal according to one or more embodiments of the present disclosure. Operations of FIG. 10, for example, may be performed in each of the first die 200a to the third die 200c illustrated in FIG. 7. Hereinafter, for convenience of description, operations of FIG. 10 performed in the first die 200a of FIG. 7 may be mainly described.

Referring to FIG. 10, a test signal provision method according to one or more embodiments of the present disclosure may include a plurality of operations S31 and S32. In one or more embodiments, operation S31 may be performed by a first test controller 270a. Operation S32 may be performed by a first core scanner 250a and a first TSV scanner 260a. That is, in operation S31, the first test controller 270a may transmit a control signal through a first control signal line 211a to the first core scanner 250a and the first TSV scanner 260a included in the first die 200a. In operation S32, based on a first control signal, a first test signal may be transmitted by the first TSV scanner 260a to a first TSV block 240a, and a second test signal may be provided by the first core scanner 250a to a first core 220a.

A first port P1 refers to an interface port for connecting a corresponding die and an external device (including an external die). The first port P1 may perform an interface function that transmits and receives a control signal, such as a test clock (TCK) signal, a test mode select (TMS) signal, a test data in (TDI) signal, a test data out (TDO) signal, and a test reset (TRSTN) signal, and may be included in the first test controller 270a to transmit the control signal or perform routing.

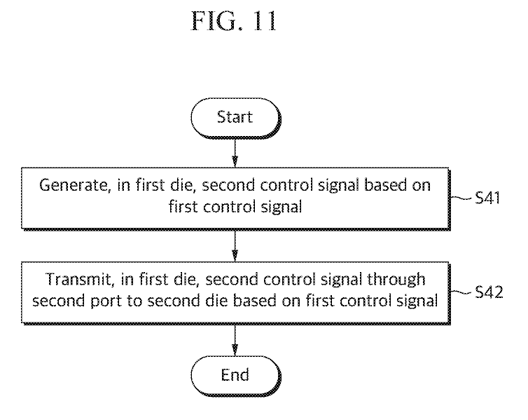

FIG. 11 is a flowchart showing a method of transmitting a control signal to another die according to one or more embodiments of the present disclosure. Operations of FIG. 11, for example, may be performed in each of the first die 200a to the third die 200c illustrated in FIG. 7. Hereinafter, for convenience of description, operations of FIG. 11 performed in the first die 200a of FIG. 7 will be mainly described.

Referring to FIG. 11, according to one or more embodiments of the present disclosure, the method of transmitting a control signal to another die may include a plurality of operations S41 and S42. In one or more embodiments, operation S41 and operation S42 may be performed by a test controller 270a. That is, in operation S41, the test controller 270a generates a second control signal based on a first control signal. In operation S42, the test controller 270a transmits the second control signal through a second port P2 to a second die 200b based on the first control signal.

Referring to FIGS. 10 and 11, the test controller 270a may receive the first control signal through a first port P1, transmit the first control signal to a core scanner 250a and a TSV scanner 260a in the first die 200a, and perform processing on the control signal through an internal logic of the test controller 270a to generate a second control signal and transmit the second control signal through the second port P2 back to an external device. The second port P2 may be a port for transmitting the generated second control signal to another external device.

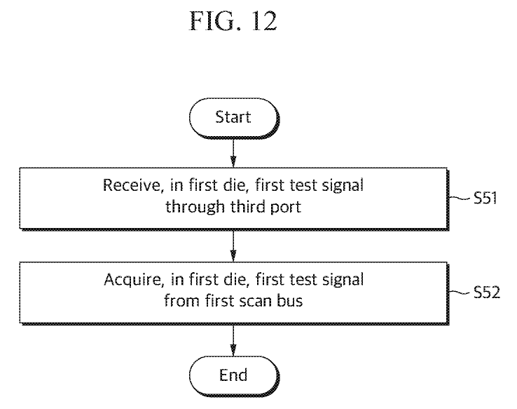

FIG. 12 is a flowchart showing a method of receiving a test signal in a die according to one or more embodiments of the present disclosure. Operations illustrated in FIG. 12, for example, may be performed in each of the first die 200a to the third die 200c illustrated in FIG. 7. However, hereinafter, for convenience of description, the operations of FIG. 11 performed in the first die 200a of FIG. 7 will be mainly described.

In one or more embodiments, operation S51 may be performed by a first scan bus 212a, and operation S52 may be performed by a first TSV scanner 260a. In operation S51, a first test signal is received through a third port P3 in the first die 200a by the first scan bus 212a. Here, the third port P3 refers to a parallel port that supports transmission of test data in parallel based on a communication protocol between dies. In one or more embodiments of the present disclosure, the third port P3 may be activated or deactivated according to a state of a die or a test condition and may be controlled to pass through or bypass a specific path. Accordingly, in the first die 200a, the first test signal streamed through the third port P3 is received.

In operation S52, the first test signal received through the third port P3 is provided to the first scan bus 212a, and the first test signal is acquired from the first scan bus 212a. Operation S52, for example, may be performed by a first TSV scanner 260a.

At least one of the components, elements, modules, units, or the like (collectively "components" in this paragraph) represented by a block or an equivalent indication (collectively “block”) in the above embodiments including the drawings such as FIGS. 1-3 and 5-7, for example, test device, test controller, core scanners, TSV scanners, cores, buses, registers, latches, or the like, may carry out the above-described function or functions. These blocks may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

As described above, example embodiments are disclosed in the figures and the specification. Although specific terms are used to describe example embodiments, such usage is merely for the purpose of describing the technical spirit of the present disclosure and is not intended to limit the meaning or restrict the scope of the disclosure as defined in the claims. Therefore, it will be understood by those skilled in the art that various modifications and equivalent other embodiments may be made based on the present disclosure.

What is claimed is:

1. A die comprising:
a scan bus configured to propagate a test signal and a response signal;
a plurality of cores;
a plurality of through silicon vias (TSVs);
a plurality of core scanners configured to be connected to the scan bus, to provide a first test signal to the plurality of cores, and to receive a first response signal from the plurality of cores; and
a first TSV scanner configured to be connected to the scan bus and to provide a second test signal to a first TSV set comprising at least one first TSV of the plurality of TSVs.

2. The die of claim 1, wherein the first TSV scanner is further configured to receive a second response signal from a second TSV set comprising at least one second TSV included in another die.

3. The die of claim 2, wherein the first TSV scanner is further configured to transmit, through the scan bus, a first resultant signal corresponding to a test result of the second TSV set based on the second test signal and the second response signal.

4. The die of claim 1, further comprising a test controller configured to receive a first control signal through a first port and to control the first TSV scanner and the plurality of core scanners based on the first control signal.

5. The die of claim 4, wherein the test controller is further configured to generate a second control signal based on the first control signal and to transmit the second control signal through a second port.

6. The die of claim 1, wherein the scan bus is further configured to receive the second test signal through a third port.

7. The die of claim 1, further comprising a second TSV scanner configured to be connected to the scan bus, and configured to provide the second test signal to a third TSV set comprising at least one third TSV of the plurality of TSVs or to receive a third response signal from a fourth TSV set included in another die.

8. The die of claim 1, wherein the first TSV set comprises at least one redundancy TSV.

9. A device comprising:
a first die comprising a first scan bus;
a second die comprising a second scan bus; and
a plurality of first through silicon vias (TSVs) connecting the first die and the second die,
wherein the first die comprises a first TSV scanner configured to receive a first test signal through the first scan bus and to provide the first test signal to a first TSV set comprising at least one of the plurality of first TSVs, and
wherein the second die comprises a second TSV scanner configured to receive a first response signal from the first TSV set and to transmit the first response signal through the second scan bus.

10. The device of claim 9, wherein the first die further comprises:
a plurality of cores; and
a plurality of core scanners configured to provide a second test signal received through the first scan bus to the plurality of cores and to transmit a second response signal received from the plurality of cores through the first scan bus.

11. The device of claim 10, wherein the first die further comprises a first test controller configured to receive a first control signal through a first port and to control the first TSV scanner and the plurality of core scanners based on the first control signal.

12. The device of claim 11, wherein the first test controller is further configured to generate a second control signal based on the first control signal and to transmit the second control signal through a second port to the second die, and
wherein the second die further comprises a second test controller configured to control the second TSV scanner based on the second control signal.

13. The device of claim 9, wherein the first scan bus is configured to receive the first test signal through a third port.

14. The device of claim 9, wherein the first die further comprises a third TSV scanner configured to receive the first test signal through the first scan bus and to provide the first test signal to a second TSV set comprising at least one of the plurality of first TSVs, and
wherein the second die further comprises a fourth TSV scanner configured to receive a third response signal from the second TSV set and to transmit the third response signal through the second scan bus.

15. The device of claim 9, wherein the first TSV set comprises at least one first redundancy TSV.

16. A method of testing a device including a first die and a second die, the method comprising:
acquiring, in the first die, a first test signal from a first scan bus;
providing, in the first die, the first test signal to a first through silicon via (TSV) set comprising at least one of a plurality of first TSVs;
acquiring, in the second die, a first response signal from the first TSV set; and transmitting, in the second die, the first response signal through a second scan bus.

17. The method of claim 16, further comprising:
acquiring, in the first die, a second test signal from the first scan bus;
providing, in the first die, the second test signal to a plurality of cores and receiving a second response signal from the plurality of cores; and
transmitting, in the first die, the second response signal through the first scan bus.

18. The method of claim 17, further comprising receiving, in the first die, a first control signal through a first port,
wherein the providing of the first test signal and the providing of the second test signal are based on the first control signal.

19. The method of claim 18, further comprising:
generating, in the first die, a second control signal based on the first control signal; and
transmitting, in the first die, the second control signal through a second port to the second die,
wherein the transmitting of the first response signal is based on the second control signal.

20. The method of claim 16, further comprising receiving, in the first die, the first test signal through a third port.
